(19) United States
(12) Patent Application Publication
(10) Pub. No.: US 2012/0216093 A1
(43) Pub. Date: Aug. 23, 2012

(54) SOFT-DECISION NON-BINARY LDPC CODING FOR ULTRA-LONG-HAUL OPTICAL TRANSOCEANIC TRANSMISSIONS

(75) Inventors: Ivan B. Djordjevic, Tucson, AZ (US); Shaoliang Zhang, Plainsboro, NJ (US); Lei Xu, Princeton, NJ (US); Fatih Yaman, Monmouth Junction, NJ (US); Ting Wang, Princeton, NJ (US)

(73) Assignee: NEC Laboratories America, Inc., Princeton, NJ (US)

(21) Appl. No.: 13/402,462

(22) Filed: Feb. 22, 2012

Related U.S. Application Data
(60) Provisional application No. 61/445,142, filed on Feb. 22, 2011.

(51) Int. Cl. H03M 13/29; G06F 11/10

(52) U.S. Cl. 714/755; 714/E11.032

(57) ABSTRACT

Methods and systems for soft-decision non-binary low-density parity-check (LDPC) coding for ultra-long-haul optical transoceanic transmissions are provided. A receiver includes one or more maximum a posteriori (MAP) equalizers configured to decode one or more symbols of an encoded input stream to provide one or more symbol log-likelihood ratios (LLRs). One or more LLR estimators are configured to estimate the log-likelihood ratios of the one or more symbol LLRs to provide one or more bit LLRs. One or more non-binary LDPC decoders are configured to decode the input stream using the one or more bit LLRs to recover an original input stream.

### RELATED APPLICATION INFORMATION

This application claims priority to provisional application Ser. No. 61/445,142 filed Feb. 22, 2011 and incorporated herein by reference in its entirety.

### BACKGROUND

1. Technical Field

The present invention relates to forward error correction for ultra-long-haul optical transoceanic transmissions, and more particularly, to systems and methods for soft-decision non-binary low-density parity-check coding schemes for ultra-long-haul optical transoceanic transmissions.

2. Description of the Related Art

In the recent years, with the rapid growth of data-centric services and the general deployment of broadband access networks, exponentially-increasing interne traffic has pushed optical communication systems to 40 Gb/s or even beyond 100 Gb/s. As the communication rate over a given medium increases, transmission becomes increasingly sensitive to errors due to various linear and nonlinear channel impairments, such as chromatic dispersion, polarization-mode dispersion (PMD) and fiber nonlinearities, thus limiting transmission distance. The Shannon limit for a noise-influenced channel describes a maximum amount of error-free data that can be transmitted with a specified bandwidth. It is therefore helpful to have robust codes and modulation schemes that closely approach the Shannon limit without imposing high requirements in terms of implementation cost and complexity.

### SUMMARY

A receiver includes one or more maximum a posteriori (MAP) equalizers configured to decode one or more symbols of an encoded input stream to provide one or more symbol log-likelihood ratios (LLRs). One or more LLR estimators are configured to use the one or more symbol LLRS to provide one or more bit LLRs. One or more non-binary LDPC decoders are configured to decode the input stream using the one or more bit LLRs to recover an original input stream.

A receiver includes a channel equalizer configured to separate an encoded input stream into at least two polarization states. One or more MAP equalizers are configured to decode one or more symbols of the input stream to provide one or more symbol LLRs. One or more LLR estimators are configured to use the one or more symbol LLRs to estimate the log-likelihood ratios of the one or more symbol LLRs to provide one or more bit LLRs. One or more non-binary LDPC decoders are configured to decode the input stream using the one or more bit LLRs. A bit de-interleaver is configured to receive the decoded stream from the one or more non-binary LDPC decoders and arrange bits of the decoded stream to recover the original input stream.

A method for receiving includes decoding one or more symbols of an encoded input stream to provide one or more symbol LLRs. LLRs of the one or more symbol LLRs are estimated to provide one or more bit LLRs. The stream is decoded with one or more non-binary LDPC decoders using the one or more bit LLRs to recover an original input stream.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 shows a block/flow diagram illustratively depicting a high-level overview of an optical transmission system/method for soft-decision non-binary low-density parity-check coding, in accordance with one embodiment;

FIG. 2 shows a block/flow diagram illustratively depicting an optical transmitter system/method for soft-decision non-binary low-density parity-check coding for ultra-long haul optical transoceanic transmission, in accordance with one embodiment;

FIG. 3 shows a block/flow diagram illustratively depicting an optical receiver system/method for soft-decision non-binary low-density parity-check coding for ultra-long haul optical transoceanic transmission, in accordance with one embodiment;

FIG. 4 shows a block/flow diagram illustratively depicting a system/method for transmitting data using soft-decision non-binary low-density parity-check coding for ultra-long haul optical transoceanic transmission, in accordance with one embodiment; and

FIG. 5 shows a block/flow diagram illustratively depicting a system/method for receiving data using soft-decision non-binary low-density parity-check coding for ultra-long haul optical transoceanic transmission, in accordance with one embodiment.

### DETAILED DESCRIPTION OF PREFERRED EMBODIMENTS

In accordance with the present principles, systems and methods are provided for soft-decision non-binary low-density parity check (LDPC) coding for ultra-long-haul (ULH) transoceanic transmissions. A transmitter interleaves information bits by arranging codewords in a non-contiguous manner to provide independent error in the channel, and thereby combating burst error. The interleaved signal is encoded using a non-binary LDPC encoder and bit mapping is performed for modulating the transmitter. The encoded signal is then transmitted over an optical medium. A receiver detects symbols from the received data stream. Channel equalization is performed on the received signal to separate the signal into two polarization states. Maximum a posteriori (MAP) equalization is performed to calculate symbol log-likelihood ratios (LLRs). The symbol LLRs are used in LLR estimation to calculate bit LLRs. Non-binary LDPC decoding is performed, using the bit LLRs, to correct errors found in the uncoded information bits. Bit de-interleaving is applied to rearrange the information bits and recover the original information bits.

This novel transmitter and receiver design of the present principles enhances system performance with the use of an LLR estimator, MAP equalizer and non-binary LDPC encoder/decoder to effectively deal with fiber nonlinearity in trans-ocean optical systems. Advantageously, this combination of structures has been shown to provide error free transmission of over 10,000 kilometers through dispersion-managed fiber. These structures can be applied to any optical system and can be easily migrated to other modulation formats and systems without any upgrade on the optical components. This improvement on fiber nonlinearity tolerance is obtained by raising the uncoded bit error rate threshold up to 4×10⁻², thus doubling the transmission distance of those systems deploying conventional forward error correction codes, such as Reed-Solomon codes.

Embodiments described herein may be entirely hardware, entirely software or including both hardware and software elements. In a preferred embodiment, the present invention is implemented in software, which includes but is not limited to firmware, resident software, microcode, etc.

Embodiments may include a computer program product accessible from a computer-usable or computer-readable medium providing program code for use by or in connection with a computer or any instruction execution system. A computer-usable or computer readable medium may include any apparatus that stores, communicates, propagates, or transports the program for use by or in connection with the instruction execution system, apparatus, or device. The medium can be magnetic, optical, electronic, electromagnetic, infrared, or semiconductor system (or apparatus or device) or a propagation medium. The medium may include a computer-readable storage medium such as a semiconductor or solid state memory, magnetic tape, a removable computer diskette, a random access memory (RAM), a read-only memory (ROM), a rigid magnetic disk and an optical disk, etc.

A data processing system suitable for storing and/or executing program code may include at least one processor coupled directly or indirectly to memory elements through a system bus. The memory elements can include local memory employed during actual execution of the program code, bulk storage, and cache memories which provide temporary storage of at least some program code to reduce the number of times code is retrieved from bulk storage during execution. Input/output or I/O devices (including but not limited to keyboards, displays, pointing devices, etc.) may be coupled to the system either directly or through intervening I/O controllers.

Network adapters may also be coupled to the system to enable the data processing system to become coupled to other data processing systems or remote printers or storage devices through intervening private or public networks. Modems, cable modem and Ethernet cards are just a few of the currently available types of network adapters.

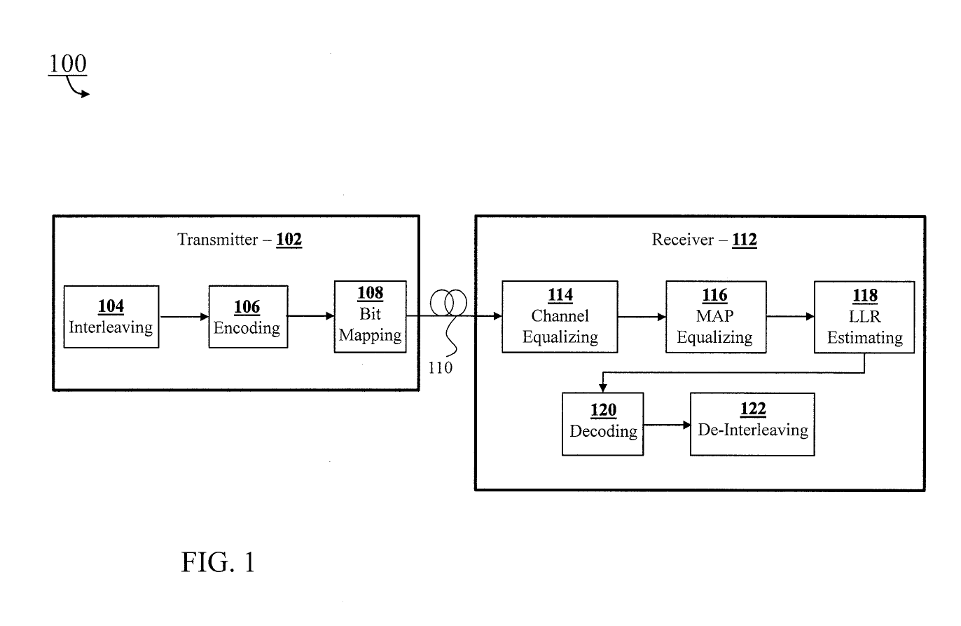

Referring now to the drawings in which like numerals represent the same or similar elements and initially to FIG. 1, block/flow diagram illustratively depicting a high-level overview of an optical transmission system/method 100 for soft-decision non-binary low-density parity-check coding is shown in accordance with one embodiment. Optical communications system 100 is shown comprising transmitter 102 and receiver 112. Transmitter 102 interleaves information bits to combat burst error in the channel at interleaving block 104. Interleaving includes arranging codewords in a non-contiguous manner such that the error in the channel is independent. In encoding block 106, the interleaved signal is encoded using a non-binary LDPC encoder to correct bit errors. Bit mapping block 108 maps each non-binary LDPC code into two binary bits, in-phase and quadrature, to drive the transmitter's 102 modulator. Transmitter 102 then sends the signal to receiver 112 over optical medium 110.

Data going through optical medium 110 becomes distorted going through the medium. Receiver 112 (e.g., coherent receiver) separates the received signal into two polarization states at channel equalizing block 114. MAP equalizing block 116 calculates one or more symbol LLRs and LLR estimating block 118 uses the one or more symbol LLRs to calculate one or more bit LLRs. At decoding block 120, one or more non-binary LDPC decoders use the one or more bit LLRs to help it make soft-decisions for error-free transmission. The signal is then de-interleaved at block 122 to recover the original information bits.

The encoders and decoders of optical communications system 100 make use of non-binary LDPC codes to provide error correction that brings the transmissions close to the channel capacity, while also reducing the latency at the receiver. Every communications channel has a channel capacity, defined as the maximum information rate that the communication channel can carry within a given bandwidth. Advantageously, the present principles improve system tolerance to fiber nonlinearity, thereby increasing the maximum reach of long-haul optical communication systems. This improvement on fiber nonlinearity tolerance is obtained by raising the uncoded bit error rate threshold up to 4×10⁻² to thereby double the transmission distance of systems deploying conventional forward error correction (FEC) codes. Moreover, these structures can be easily migrated to other modulation formats and systems without any upgrade of the optical components.

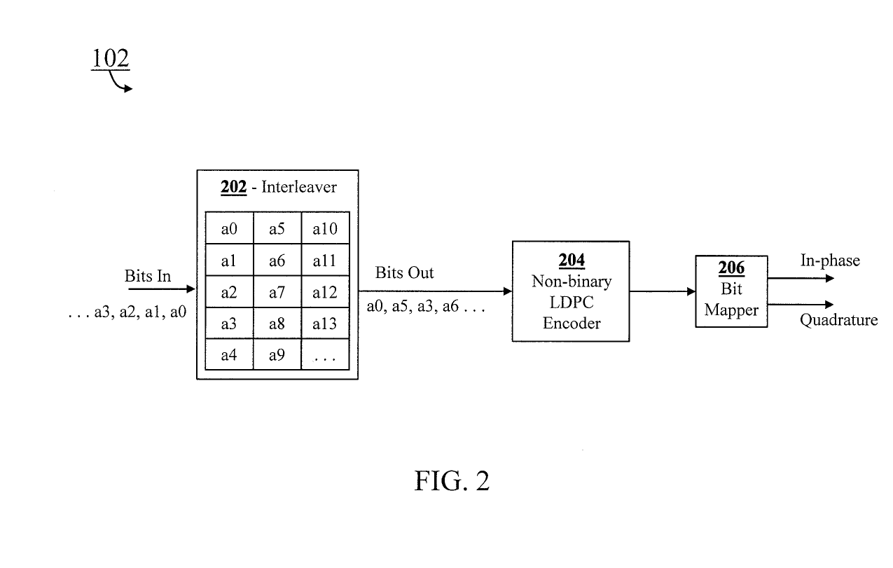

Referring now to FIG. 2, a block/flow diagram illustratively depicting an optical transmitter system/method 102 for soft-decision non-binary low-density parity-check coding for ultra-long haul optical transoceanic transmission is shown in accordance with one embodiment. Information bits are fed into interleaver 202. In a preferred embodiment, the information bits are combined by interleaver 202 in a column-writing and row-reading manner. Bit interleaving is a way to arrange information bits in a non-contiguous manner to increase performance, especially with respect to forward error correcting codes. In communication channels, errors typically occur in bursts rather than independently. Interleaving ameliorates this problem by shuffling information bits across several codewords, thereby creating a more uniform distribution of errors. Bit interleaver 202 arranges codewords in the signal to combat burst error due to time-varying fiber effects such that the bursty channel is transformed into a channel having independent error. For example, as illustratively depicted in FIG. 2, interleaver 202 receives bits . . . , a3, a2, a1, a0 and outputs bits a0, a5, a3, a6, . . . . The output of inteleaver 202 is sent to non-binary LDPC encoder 204.

Non-binary LDPC encoder 204 encodes the signal to correct bit error and help improve fiber nonlinearity tolerance. LDPC code is a linear block code whose parity-check matrix has a low-density of nonzero entries. A q-ary LDPC code is given by the null-space of a sparse parity-check matrix defined over the Galois (or finite) field of q elements, denoted as GF(q). The parity-check matrix of a q-ary LDPC code can be constructed by assigning nonzero elements from the Galois field of order q to the 1's in that of the corresponding binary LDPC code. When q=2^{m}, where m is any positive integer (i.e., when the LDPC code is defined over an extension of the binary field), m=1 represents binary LDPC codes, while m=2 represents 4-ary LDPC codes. Binary LDPC coding refers to LDPC codes that are binary (i.e., either 0 or 1). Non-binary LDPC coding has an output of 0 to 2^{N} different levels, where N is any positive integer, depending on the non-binary LDPC design.

Compared with binary LDPC code, coded multilevel modulation schemes employing non-binary LDPC codes as component codes have been shown to be promising advances in forward error correction. Non-binary LDPC coding has been shown to outperform binary LDPC coding by providing lager coding gains, while also reducing latency at the receivers by avoiding costly turbo-equalization iterations. In a preferred embodiment, non-binary LDPC encoder 204 is a 4-ary LDPC encoder. However, as discussed above, it is noted that this setup is generic, as non-binary LDPC encoder 204 can be applied for any 2^{m}-ary LDPC coding scheme, where m is a positive integer. The output of the, e.g., 4-ary non-binary LDPC encoder 204 corresponds to quadrature phase-shift-keying (QPSK) symbols, not a bit sequence.

Bit mapper 206 maps each 4-ary non-binary LDPC code into two binary bits, in-phase and quadrature, for modulating the transmitter. In one embodiment, the encoded sequence is mapped according to the following symbol-to-bit mapping: 0→(0, 0); 1→(0, 1); 2→(1, 0); and 3→(1, 1). However, other mapping sequences are also contemplated. Transmitter 102 launches the bits into the optical medium to achieve long-haul transmission.

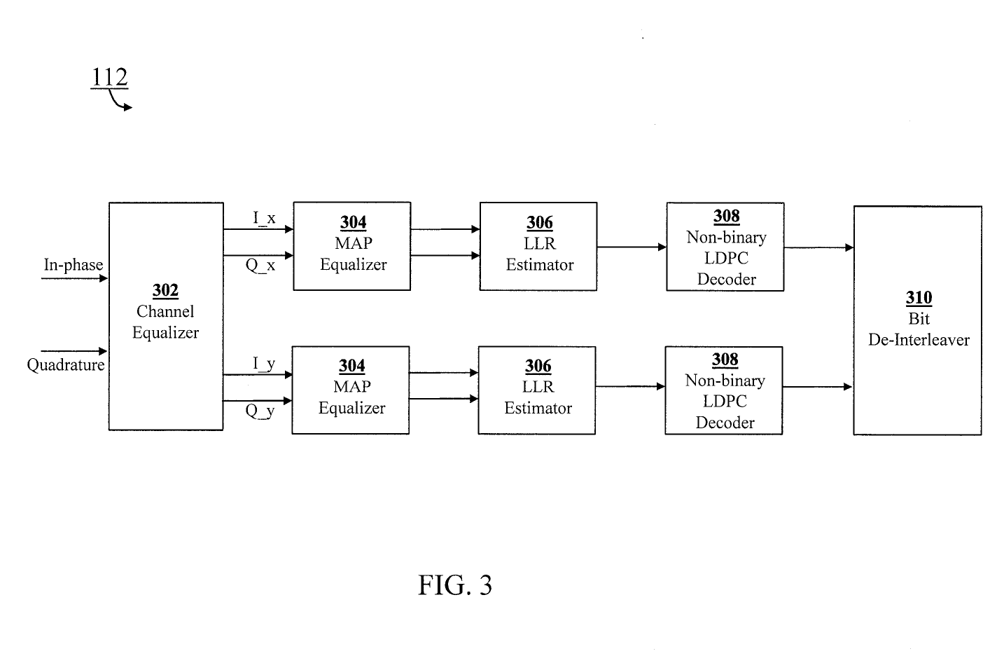

Referring now to FIG. 3, a block/flow diagram illustratively depicting an optical receiver system/method 112 for soft-decision non-binary low-density parity-check coding for ultra-long haul optical transoceanic transmission is shown in accordance with one embodiment. Receiver 112 receives the encoded data stream and detects symbols. A series of digital signal processing steps is performed by receiver 112 to recover the original information bits. As the data travels through the optical medium, the data becomes distorted by the channel. Channel equalizer 302 separates the received in-phase and quadrature bits into two polarization states and restores the waveform.

One or more maximum a posteriori (MAP) equalizers 304 implement, for example, sliding-window-based Bahl-Cocke-Jelinek-Raviv method (SW-BCJR-MAP), which is known in the art. Other methods are also contemplated. The SW-BCJR-MAP method operates on a discrete dynamical trellis description of the optical medium to perform symbol decoding to minimize the uncoded bit error rate (BER) through the correlation of symbols. MAP equalizers 304 determine symbol LLRs on each polarization branch and are input to corresponding LLR estimators 306.

One or more LLR estimators 306 compute an estimated LLR on each polarization branch. LLR estimators 306 use the one or more symbol LLRs from corresponding MAP equalizers 304 to compute one or more bit LLRs. The one or more bit LLRs are used by corresponding non-binary LDPC decoders 308 to help render more accurate information on the channel characteristics. LLR estimators 306 use a training method to estimate the logarithm of the ratio of the conditional probability that the k-th symbol sent by the transmitter is {0, 1, 2, 3} (constellation of QPSK) over the probability that it is 0 (reference symbol) given the received noisy signal. The bit LLRs provide LDPC decoders 308 with the probability of each bit in order to make soft decisions and determine the codeword sent by the transmitter. Soft-decision detection is performed by receiving information indicating the reliability of each input data point to form better estimates of the input data. Soft-decision detection sets several decision thresholds, each associating a probability that the decision is correct. A higher probability will result in a more accurate decision.

Non-binary LDPC decoders 308 process the one or more bit LLRs from LLR estimators 306 to correct errors found in the uncoded symbols through a non-binary LDPC check matrix to achieve error-free transmission. In one embodiment, MAP equalizers 304, LLR estimators 306 and non-binary LDPC decoders 308 are cascaded such that two or more groups, including MAP equalizer 304, LLR estimator 306 and non-binary LDPC decoder 308, are run in parallel by processing portions of the received block in parallel. In this way, processing over the entire block is avoided, as it may become inhibitive as the block (i.e., codeword) length increases. The final bits are de-interleaved by bit de-interleaver 310 to re-arrange the signal in the same order as the original information bits to result in the recovered information bits.

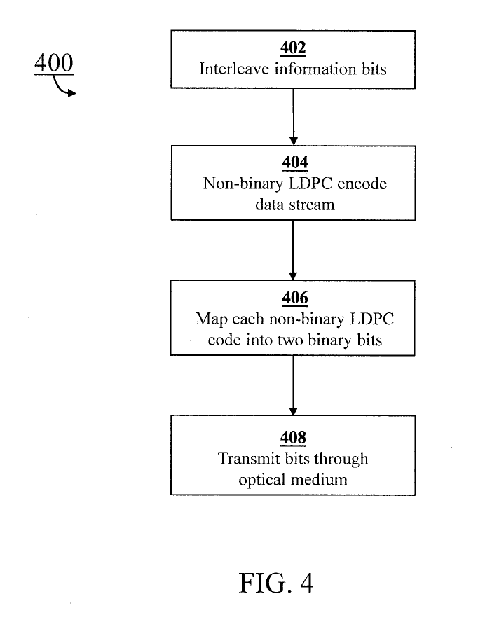

Referring now to FIG. 4, a block/flow diagram illustratively depicting a system/method for transmitting data 400 using soft-decision non-binary low-density parity-check coding for ultra-long haul optical transoceanic transmission is shown in accordance with one embodiment. In block 402, information bits are interleaved for dealing with possible burst errors due to time-varying fiber effects. Bit interleaving includes arranging information bits in a non-contiguous manner, such that the bursty channel is transformed into a channel having independent error, thereby combatting burst error in the channel. In a preferred embodiment, the information bits are interleaved in a column-writing and row-reading manner.

In block 404, the interleaved bits are encoded using a non-binary LDPC code for bit error correction. In one preferred embodiment, non-binary LDPC encoder is a 4-ary non-binary LDPC encoder. However, it is noted that non-binary LDPC encoder can be any 2^{m}-ary LDPC encoder, where m is a positive integer. Non-binary LDPC coding has been shown to outperform binary LDPC coding by providing lager coding gains, while also reducing latency at the receivers by avoiding costly turbo-equalization iterations. The output of the, e.g., 4-ary non-binary LDPC encoder corresponds to quadrature phase-shift-keying (QPSK) symbols, not a bit sequence.

In block 406, each non-binary LDPC code is mapped to two binary bits, in-phase and quadrature, for modulating the transmitter. In one embodiment, the non-binary LDPC code is mapped according to the following symbol-to-bit mapping: 0→(0, 0); 1→(0, 1); 2→(1, 0); and 3→(1, 1). Other mapping methods are also contemplated. In block 408, the transmitter takes the bits from the bit mapping to modulate the optical signal, which is sent through an optical channel to achieve ultra-long-haul transmission.

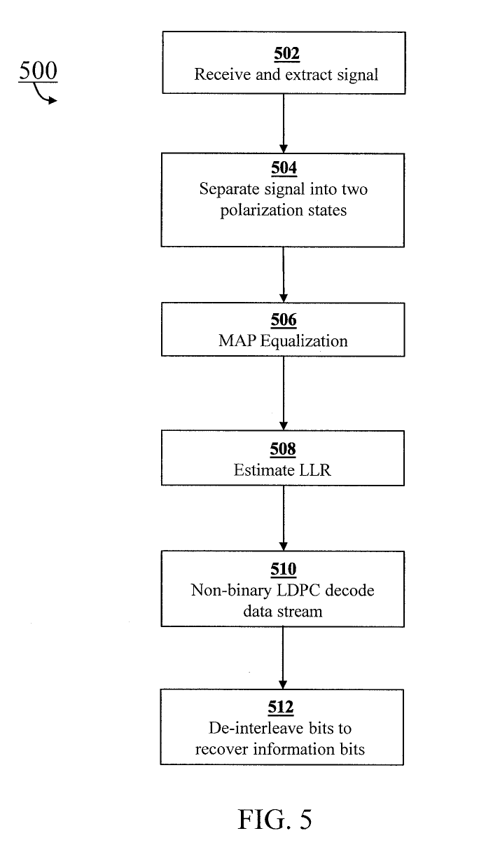

Referring now to FIG. 5, a block/flow diagram illustratively depicting a system/method for receiving data 500 using soft-decision non-binary low-density parity-check coding for ultra-long haul optical transoceanic transmission is shown in accordance with one embodiment. In block 502, the optical signal is extracted into the electrical domain to perform a series of digital signal processing steps to recover the original information bits. As data is transmitted through the optical medium, the data becomes distorted by the medium. In block 504, channel equalization is performed to separate the signal into two polarization states. In block 506, MAP equalization is performed to minimize uncoded bit error rate through correlation between symbols. The output of MAP equalization can be treated as symbol LLRs. In one preferred embodiment, a SW-BCJR-MAP method is implemented. Other methods are also contemplated.

In block 508, LLR estimation is performed to compute bit LLRs on each polarization branch from the symbol LLRs of the MAP equalization. The LLR estimates the logarithm of the ratio of the conditional probability that the k-th symbol sent by the transmitter is {0, 1, 2, 3} (constellation of QPSK) over the probability that it is 0 (reference symbol) given the received noisy signals. Symbol LLRs from MAP equalization are used in LLR estimation to provide bit LLRs. Bit LLRs are subsequently utilized in LDPC decoding to provide probability estimates for each bit. In block 510, LDPC decoders process bit LLRs as initial reliability estimates. LDPC decoders correct all the errors found in the uncoded symbols through a non-binary LDPC check matrix to achieve error-free transmission.

In one embodiment, the steps of MAP equalization, LLR equalization and non-binary LDPC decoding are cascaded such that two or more groups implementing the steps of MAP equalization, LLR equalization and non-binary LDPC decoding are run in parallel, each group processing a portion of the received block. In this way, processing over the entire block is avoided, as it may become inhibitive as the block (i.e., codeword) length increases. In block 512, the final bits are de-interleaved to recover the original information bits.

Having described preferred embodiments of a system and method of soft-decision non-binary LDPC coding for ultra-long-haul optical transoceanic transmissions (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A receiver, comprising:
one or more maximum a posteriori (MAP) equalizers configured to decode one or more symbols of an encoded input stream to provide one or more symbol log-likelihood ratios (LLRs);
one or more LLR estimators configured to use the one or more symbol LLRs to estimate the log-likelihood ratios of the one or more symbol LLRs to provide one or more bit LLRs; and
one or more non-binary low-density parity-check (LDPC) decoders configured to decode the input stream using the one or more bit LLRs to recover an original input stream.

2. The receiver as recited in claim 1, wherein the MAP equalizers, LLR estimators and non-binary LDPC decoders are cascaded such that two or more groups including the MAP equalizer, LLR estimator and non-binary LDPC decoder are run in parallel.

3. The receiver as recited in claim 1, wherein the non-binary LDPC decoder further comprises a 2^{m}-ary non-binary LDPC decoder, wherein m is any positive integer.

4. The receiver as recited in claim 1, further comprising:
a channel equalizer configured to separate the input stream into at least two polarization states.

5. The receiver as recited in claim 1, further comprising:
a bit de-interleaver configured to receive the decoded stream from the one or more non-binary LDPC decoders and arrange bits of the stream to recover the original input stream.

6. The receiver as recited in claim 1, wherein the one or more MAP equalizers are configured to perform trellis calculations on the one or more symbols of the input stream.

7. The receiver as recited in claim 1, wherein the one or more MAP equalizers are configured to implement a sliding-window-based Bahl-Cocke-Jelinek-Raviv method.

8. A receiver, comprising:
a channel equalizer configured to separate an encoded input stream into at least two polarization states;
one or more maximum a posteriori (MAP) equalizers configured to decode one or more symbols of the input stream to provide one or more symbol log-likelihood ratios (LLRs);
one or more LLR estimators configured to use the one or more symbol LLRs to estimate the log-likelihood ratios of the one or more symbol LLRs to provide one or more bit LLRs;
one or more non-binary low-density parity-check (LDPC) decoders configured to decode the input stream using the one or more bit LLRs; and
a bit de-interleaver configured to receive the decoded stream from the one or more non-binary LDPC decoders and arrange bits of the stream to recover an original input stream.

9. The receiver as recited in claim 8, wherein the MAP equalizers, LLR estimators and non-binary LDPC decoders are cascaded such that two or more groups including the MAP equalizer, LLR estimator and non-binary LDPC decoder are run in parallel.

10. The receiver as recited in claim 8, wherein the non-binary LDPC decoder further comprises a 2^{m}-ary non-binary LDPC decoder, wherein m is any positive integer.

11. The receiver as recited in claim 8, wherein the one or more MAP equalizers are configured to perform trellis calculations on the one or more symbols of the input stream.

12. The receiver as recited in claim 8, wherein the one or more MAP equalizers are configured to implement a sliding-window-based Bahl-Cocke-Jelinek-Raviv method.

13. A method for receiving, comprising:
decoding one or more symbols of an encoded input stream to provide one or more symbol log-likelihood ratios (LLRs);
estimating the log-likelihood ratios of the one or more symbol LLRs to provide one or more bit LLRs; and
decoding the stream with one or more non-binary low-density parity-check (LDPC) decoders using the one or more bit LLRs to recover an original input stream.

14. The method as recited in claim 13, wherein the steps of decoding one or more symbols, estimating the LLRs, and decoding the stream are cascaded such that two or more groups including the steps of decoding one or more symbols, estimating the LLRs, and decoding the stream, are run in parallel.

15. The method as recited in claim 13, wherein the non-binary LDPC decoder further comprises a 2^{m}-ary non-binary LDPC decoder, wherein m is any positive integer.

16. The method as recited in claim 13, further comprising:
separating the input stream into at least two polarization states.

17. The method as recited in claim 13, further comprising:
arranging bits of the decoded stream to recover the original input stream.

18. The method as recited in claim 13, wherein the decoding one or more symbols includes performing trellis calculations on the one or more symbols of the input stream.

19. The method as recited in claim 13, wherein the decoding one or more symbols includes implementing a sliding-window-based Bahl-Cocke-Jelinek-Raviv method.

20. A computer readable storage medium comprising a computer readable program, wherein the computer readable program when executed on a computer causes the computer to perform the steps of claim 13.
